(19) United States
(12) Patent Application Publication
(10) Pub. No.: US 2011/0128766 A1
(43) Pub. Date: Jun. 2, 2011

(54) Programmable Resistance Memory

(76) Inventor: Ward Parkinson, Boise, ID (US)

(21) Appl. No.: 12/626,988

(22) Filed: Nov. 30, 2009

(51) Int. Cl. G11C 5/06; G11C 11/00

(52) U.S. Cl. 365/63; 365/163; 365/185.17

(57) ABSTRACT

A nonvolatile integrated circuit memory includes mode control circuitry that allows it to be configured as any of a plurality of memory types.

### FIELD OF INVENTION

This invention relates to electronic memory devices and, in particular, to integrated circuit memory devices.

### BACKGROUND OF THE INVENTION

A variety of integrated circuit (IC) memory types have evolved to take advantage of the particular features of their base technologies and to suit different applications. Along with the evolution of divergent technologies, the interfaces of different types of memories have evolved away from one another to adapt to different applications and technologies. Although there tends to be commonality among specific memory types, interfaces vary markedly from type to type, and differences appear in the physical, temporal, and procedural aspects of the interfaces. Physical differences among interfaces may include differences in pin assignment, also referred to herein as “pinout,” temporal differences may include setup times, for example, and procedural differences may include differences between “command/register” access and direct, memory-mapped, access procedures, for example.

The different cell structures and different array configurations associated with various memory technologies have determined the variety of interfaces employed by integrated circuit memories. An integrated circuit memory technology that can address more than one, and possibly all, of the application areas promises to reduce costs, in part, by economies of scale; if all integrated circuit memory applications could be served by a single technology, that single technology would enjoy a significant volume advantage over even the most popular integrated circuit memory technology of today.

Given the significant installed base of software, drivers, and memory controllers, any integrated circuit memory technology that purports to serve markets currently served by multiple integrated circuit memory technologies must accommodate the different interfaces associated with each of the targeted technologies. One way to accommodate the various interfaces is to define the target memory type through use of one or more masks specific to the target memory type during manufacturing. With the core memory array remaining the same, an interface for each type could be implemented using different target-specific masks for a limited number of layers. Each additional mask adds significant expense, though, often in the millions of dollars. Additionally, the manufacturing process itself is rendered more complex and, concomitantly, more expensive by the use of multiple masks. A method and apparatus that allow a single type of memory to substitute for a variety of integrated circuit memory types without employing specialized masks to implement different interfaces would be highly desirable.

### SUMMARY

A nonvolatile integrated circuit (IC) memory in accordance with the principles of the present invention includes an array of nonvolatile memory elements, input/output (I/O) circuitry, and memory mode control circuitry that allows the memory to adapt to any one of a plurality of IC memory interfaces. Such interfaces may include NAND FLASH, NOR FLASH, dynamic random access memory (DRAM), or synchronous dynamic random access memory (SDRAM), for example.

Mode control circuitry in accordance with the principles of the present invention may reconfigure one or more signal paths between I/O contact(s) and memory circuitry. The memory circuitry may include memory access circuitry such as decoders, registers, I/O drivers, or latches, for example, in addition to an array of nonvolatile memory elements. In an illustrative embodiment, the nonvolatile memory is a programmable resistance memory, such as a phase change memory (PCM). Illustrative modes of operation include a NAND FLASH emulation mode, also referred to herein simply as a NAND mode; a NOR FLASH emulation mode, also referred to herein as a NOR mode; a dynamic random access memory (DRAM) emulation mode, also referred to herein as a DRAM mode; and a synchronous dynamic random access memory (SDRAM) emulation mode, also referred to herein as an SDRAM mode.

In addition to, or in place of, reconfiguring one or more signal paths to adapt to a particular memory interface, a memory in accordance with the principles of the present invention may alter its functional interface to external circuitry. For example, when emulating a NAND device, the memory may accept and interpret a NAND access command and place a received multi-part address in an access register, then provide access to a block of data in order to emulate a block mode access typical of NAND devices. On the other hand, when emulating a DRAM or NOR device, a memory in accordance with the principles of the present invention may provide a memory-mapped direct-access to memory elements within its array, along with the requisite handshaking signals, such as “output enable,” or “busy,” for example. In multi-level cell (MLC) embodiments a memory in accordance with the principles of the present invention provides a transparent memory-memory mapping to on-chip memory. In illustrative embodiments, a multi-mode nonvolatile memory in accordance with the principles of the present invention may produce information, handshaking and timing signals to emulate any of a plurality of memory interfaces. For example, the memory may produce a “bad block” list to accommodate a NAND FLASH interface.

Mode control settings may be implemented by tying mode control contacts to high, low, or intermediate logic levels at the memory manufacturing facility, at an original equipment manufacturer's facility, or at an end user's facility, for example. In accordance with the principles of the present invention, mode control settings may be downloaded to a memory in accordance with the principles of the present invention. When downloaded, the mode control settings may be security-enabled, requiring a security code input for operation, for example.

A nonvolatile memory that accommodates a plurality of memory interfaces in accordance with the principles of the present invention may be particularly suitable for operation in a variety of electronic devices, including cellular telephones, radio frequency identification devices (RFID), computers (portable and otherwise), solid state drives (SSDs), location devices (e.g., global positioning system (GPS) devices, particularly those that store and update location-specific information), and handheld electronic devices, including personal digital assistants (PDAs), and entertainment devices, such as MP3 players, for example.

### BRIEF DESCRIPTION OF THE DRAWINGS

FIG. 1 is a block diagram of an integrated circuit nonvolatile memory that includes an array of nonvolatile memory elements, mode control circuitry and input/output (I/O) circuitry in accordance with the principles of the present invention;

FIG. 2 is a block diagram of I/O circuitry in accordance with the principles of the present invention; and

FIG. 3 is a block diagram of an electronics system that operates in accordance with the principles of the present invention.

### DETAILED DESCRIPTION

Although this invention will be described in terms of certain preferred embodiments, other embodiments that are apparent to those of ordinary skill in the art, including embodiments that do not provide all of the benefits and features set forth herein, are also within the scope of this invention. Various structural, logical, process step, chemical, and electrical changes may be made without departing from the spirit or scope of the invention. Polarities and types of devices and supplies may be substituted in a manner that would be apparent to one of reasonable skill in the art. Process descriptions may include flowcharts that illustrate various steps taken in a process. Such flowcharts and accompanying discussion are not meant to be an exhaustive explanation of every step and every procedure in such a process. Rather, they are meant to provide a description with sufficient detail to enable one of ordinary skill in the art to practice and use the invention. In some embodiments, additional steps may be employed or steps may be carried out in a different sequence than set forth in the flowchart and associated discussion. Although a variety of nonvolatile memory technologies are contemplated within the scope of the invention, for clarity and brevity of description, the illustrative embodiments will generally be given in terms of phase change memory implementations. Accordingly, the scope of the invention is defined only by reference to the appended claims.

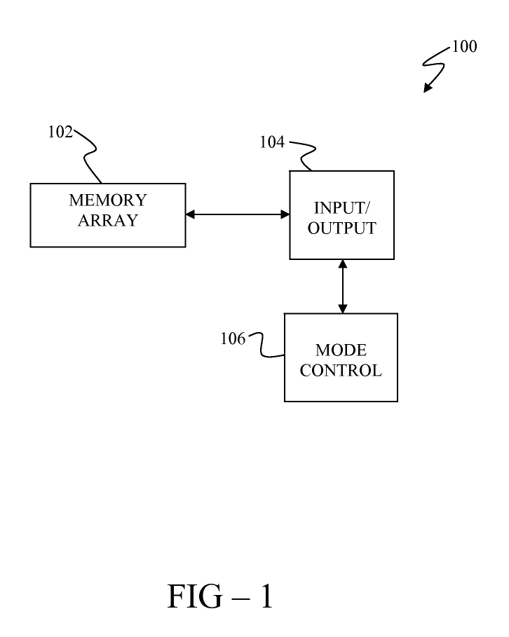

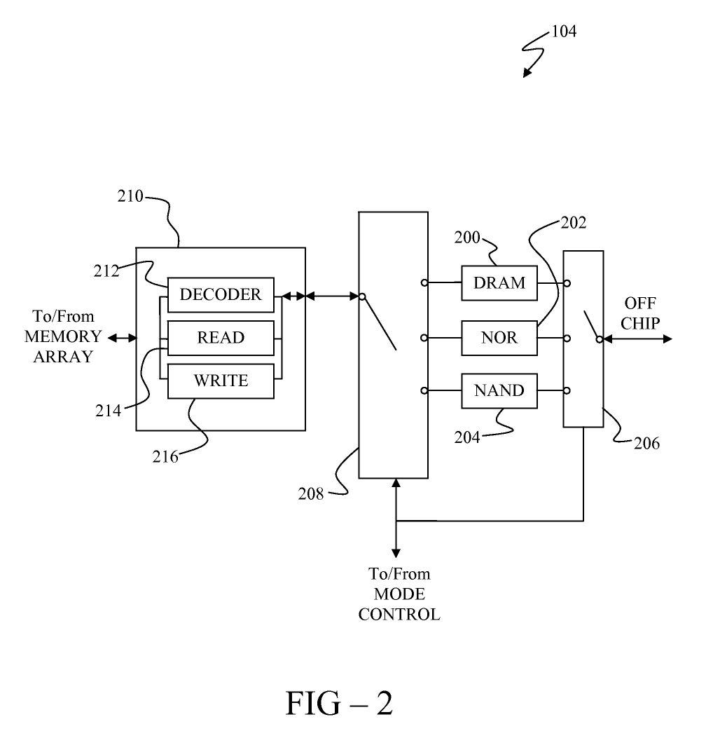

The block diagram of FIG. 1 illustrates components of a nonvolatile IC memory 100 in accordance with the principles of the present invention. The nonvolatile memory 100 includes an array of nonvolatile memory elements 102 which may be arranged in one or more rectangular hierarchical arrays. In an illustrative embodiment the nonvolatile memory array 102 employs phase change memory (PCM) cells. Cells within the array 102 may be accessed through input/output (I/O) circuitry 104, where the bit may be selected by x and y decoders, as is familiar to those reasonably skilled in the art. As will be described in greater detail in the discussion related to FIG. 2, I/O circuitry 104 may include address lines, data lines, a read signal line, a write signal line, decoding circuitry, registers, drivers, latches, and various chip enable and strobe lines, for example. The I/O circuitry 104 provides an interface between off-chip (that is, circuitry located on a separate integrated circuit or circuits) and on-chip circuitry (that is, circuitry located on the same integrated circuit) and, in particular, between off-chip circuitry and the on-chip array of memory cells 102. In accordance with the principles of the present invention, the memory mode control circuitry 106 allows the memory 100 to adapt to any one of a plurality of integrated circuit memory interfaces, such as NAND FLASH, NOR FLASH, dynamic random access memory (DRAM), or synchronous dynamic random access memory such as DDR or SDRAM, for example.

The mode control circuitry 106 may be configured to alter one or more signal paths between input/output (I/O) contacts, or pins, and memory circuitry in order to, for example, route a signal from a pin that is used for one function in one type of memory and for a different function in another type of memory. Signals from a pin defined as an I/O pin in a NAND FLASH emulation mode may be directed to an input register. The same pin may be defined as an address line in DRAM or NOR FLASH emulations and signals from that pin may be directed to a decoder when the memory is operating in those modes, for example.

Mode control circuitry 106 may be implemented using a state machine, reduced instruction set processor, a programmable array, custom logic, a microcode device, static or dynamic control logic, or a bit-slice processor core, for example. Circuitry associated with error detection and correction, particularly an error detection and correction core, may be used to carry out all or a part of the mode control functions. The rerouting of signal lines may be implemented, for example, using phase change material as a programmable interconnect. Selection of a mode with mode control circuitry 106 may be via separate pins or by electronic key(s) that are loaded from I/O and stored in a register within mode control circuitry 106 that enables and controls mode selection. Electronic keying may be enabled by presenting a specific byte (if x8 mode on output) or word (if x16 mode on output). The byte may then be loaded or followed by a byte or bytes that are loaded into mode control circuitry 106. The byte(s) may then be used until the chip is re-keyed to a different mode. Such bytes may be stored on-chip in non-volatile memory or loaded after restoring power to the chip.

In addition to, or in place of, reconfiguring one or more signal paths to adapt to a particular memory interface, mode control circuitry 106 may alter its functional interface to external circuitry. For example, when emulating a NAND device, the memory may accept and interpret some or all of a NAND access command set and place a received multi-part address in an access register in order to emulate a block mode access typical of NAND devices. The mode control circuitry 106 may be keyed to define that the state written by a “1” is a low resistance or high resistance state, and similarly that the state written for a “0” is then respectively a high or low resistance. The mode control circuitry 106 may be keyed to define that MLC is enabled to write and read more than one level in each physical cell and a micro-controller in mode control circuitry may accordingly sequence the chip to write-read-verify-rewrite to the preferred level.

On the other hand, when emulating a DRAM or NOR device, the mode control circuitry 106 may provide a memory-mapped direct-access to memory elements within the array 102, along with the requisite handshaking signals, such as output enable, for example. In multi-level cell (MLC) embodiments the mode control circuitry 106 may provide a transparent memory-memory mapping to on-chip memory. In illustrative embodiments, the mode control circuit 106 may produce data, handshaking and timing signals to emulate any of a plurality of memory interfaces, including, for example, a “bad block” list to accommodate a NAND Flash interface.

Mode control settings may be implemented by tying mode control contacts to high, low, or intermediate logic levels at the memory manufacturing facility, at an original equipment manufacturer's facility, or at an end user's facility, for example, downloaded to the user such as via a computer hard-wired interface or via the internet. In accordance with the principles of the present invention, mode control settings may be downloaded to a memory in accordance with the principles of the present invention. When downloaded, the mode control settings may be security-enabled, requiring a security code input for operation, for example.

The block diagram of FIG. 2 provides a more detailed functional view of an I/O block 104 in accordance with the principles of the present invention. In this illustrative embodiment the I/O circuitry include DRAM 200, NOR FLASH 202, and NAND FLASH 204 interfaces. The DRAM interface 200 may include circuitry and control logic that accommodates various forms of DRAM, including SDRAM and DDR, for example. The mode select input, may be from chip pins or mode control circuitry 106 (which may be an on-chip register loaded by electronic key such as, for example, from I/O block 104 in FIG. 1). The mode select input selects among the available interfaces, employing physical or electronic switches 206 and 208. Such switches may be made by bonding pads high or low, storing in volatile memory or storing in non-volatile memory. Loading of such storage may be upon power-up from an external controller, and such loading shall be on each power-up if the storage is in volatile memory (or if refresh is desired for the non-volatile memory).

The switch 206 routes signals, including data, address, and control signals between pins at the physical interface of the memory 102 and circuitry off-chip. Additionally, functional aspects of the individual interfaces, such as timing and register usage, are selected by the switch 206. Similarly, the router switch 208 routes signals from a selected interface to array interface circuitry 210, which includes decoder 212, read circuitry 214, and write circuitry 216. One or more signals from the array interface circuitry 210 is directed to the memory's storage cell array 102. The decoder 212, read circuitry 214, and write circuitry 216 may be implemented using known technology, with, for example, the decoder circuitry applying a current having different timing, amplitude, and slope characteristics across a selected phase change storage element to effect a read or a write operation.

The DRAM interface 200, such as may be employed by a multi-mode nonvolatile memory in accordance with the principles of the present invention may include write enable (typically an active low signal), row address strobe (RAS), and column address strobe (CAS), as well as data Dn and address An signal contacts. The DRAM interface 200 routes signals between their DRAM-defined pin locations and the array interface circuitry 210. In an illustrative embodiment in which memory cells in the array 102 are phase change memory cells, the decoder 212 may have registers loaded by multiplexing inputs from the I/O pins, from row and column addresses that are provided sequentially from the I/O pins that are latched into the decoder 212 in a manner consistent with DRAM addressing, using RAS and CAS signals to select the row and column address lines, respectively. The same pins may be used in the cycle to load Din or read out Dout to the address pins.

In illustrative embodiments, the integrated circuit memory may be arranged as bit-, byte-, word-, or long-word-wide memory. As previously noted, one or more of the I/O pins of the device may be rerouted to accommodate different pin definitions for the different memory interface types. A pin that serves as a data line for a DRAM operational mode may serve as an I/O line for a NAND FLASH interface type, for example.

The DRAM interface 200 includes circuitry that may be employed to emulate conventional DRAM, or SDRAM. Additionally, a plurality of other formats, including, registered, DDR, DDR2, and DDR3 may be accommodated. In an illustrative embodiment, a nonvolatile IC memory in accordance with the principles of the present invention divides its memory array 102 into a plurality of banks when operating in an SDRAM mode, with N rows and M columns and M sense amplifiers connected, one each, to the column lines of an active memory bank. Each bank may be activated by a command that may be issued internally or by an external (that is, off-chip) memory controller, for example.

Activation connects an addressed row of memory elements to the M sense amplifiers and thereby allows the contents of the addressed memory elements to be read. In phase change embodiments within the scope of the invention, such reads are non-destructive. Once a row is activated, read and write operations may be performed upon cells within the bank, with the delay between operations determined by the time required to access an individual column within the activated bank. In this manner, cells within an activated row may be selected rapidly (optionally, bit-wide, byte-wide, or other width, for example) in what may be referred to as a burst mode, requiring only the column address setup time for each subsequent access.

In an illustrative embodiment the mode control circuitry 106 includes a mode register into which the number of sequential accesses to be performed may be stored. An external circuit may thereby access a sequential series of memory locations by delivering a start address, followed by the number of locations (that is, length of burst) required. In an illustrative embodiment, a mode register is employed to indicate not only which general mode the memory is operating in (NAND, NOR, SDRAM, for example), it also stores mode-specific information. Such mode-specific information may include burst type (sequential vs. interleaved), burst length, or write burst mode, for an SDRAM operation, for example.

As previously indicated, 1 or more of various implementations of SDRAM, or subsequent generations of double data rate (DDR2, DDR3, and DDR4, for example) may be accommodated by a multi-mode nonvolatile memory in accordance with the principles of the present invention. As a part of that accommodation, a nonvolatile multi-mode integrated circuit memory in accordance with the principles of the present invention may include a mechanism for identifying itself and describing its capabilities. Such a mechanism may, for example, encompass the serial presence detection feature of SDRAM devices and similar identification mechanisms employed by other memories, such as NAND FLASH and NOR FLASH devices, including, for example, providing upon command the Read ID or Read Unique information that identifies the chip and its selected mode. In an illustrative embodiment, all SDRAM modes supported by a multi-mode nonvolatile integrated circuit memory in accordance with the principles of the present invention may conform to some or all Joint Electron Device Engineering Council (JEDEC) standards for one or more interfaces.

In an illustrative embodiment, a multi-mode nonvolatile integrated circuit memory may be in accordance with the principles of the present invention conforms, in its NAND FLASH mode, to some or all of the open NAND FLASH interface (ONFI) standards. As such, in its NAND mode, the memory conforms to standard timing requirements for NAND FLASH and may employ some or all of a standard command set for reading, writing, and erasing NAND FLASH. Generally, in the NAND mode the interface is similar to that required of a peripheral cpu, driver or interface device.

Physically, such an interface is manifested in the fact that there are no address-dedicated pins, just I/O pins that may serve double duty by operating as both address (row or column) pins or data pins. As previously indicated, a multi-mode nonvolatile integrated circuit memory in accordance with the principles of the present invention re-assigns and re-routes interface signals, as necessary, to conform to the pinout requirements of the mode (NAND, NOR, SDRAM, for example) in which it is programmed to operate.

Functionally, in the NAND mode, the interface may be similar to that of a peripheral device, in that all data, address, and commands pass through the I/O signal lines. In an illustrative NAND embodiment, data is read from the array 102 in page-sized blocks. The size of page may be determined, as with other selections, by setting mode control values during the integrated circuit memory manufacturing process or during OEM integration, for example.

In an illustrative embodiment in conformity with NAND operation, data is provided from the array 102 in multi-bit pages. The pages may be of any size which can be defined off or on chip in the mode control circuitry 106 by loading, for example, from off-chip during operation or pre-loading at the factory for more permanent definition such as in one-time programmable memory or reversible non-volatile memory. In this illustrative embodiment emulating, for example, a NAND interface, the pages are 256 bytes deep plus eight bytes for redundancy and error correcting code (ECC). A read begins with a read command followed by multiple cycles of address information. The address information indicates which page to pull from the array 102 and where to set a pointer within the page. In such a read operation, data is ready to be read from the page only after a latency delay (e.g. 25 microseconds with NAND as the memory cell technology). In an illustrative phase change memory element embodiment, the delay may be unnecessary and the mode control circuitry 106 either provides the data immediately and may then release the Ready/Busy pin, thereby accelerating the operation of a system that employs such a memory, or the mode control circuitry 106 performs other operations during a delay time inserted to conform to conventional NAND FLASH operation. After the delay, data may be read out, a byte at a time, from consecutive locations starting at the address indicated by the pointer, for part or all of the page.

A write operation may be executed by sending a write command (also referred to herein as a programming data input command), followed by a multi-cycle address input, data input, and, finally, a program command. A handshaking signal, ready/busy, is used to indicate to external circuitry that a programming operation is taking place (busy) and further access to the device is held off until the programming is complete (ready). This delay can be significant, on the order of hundreds of microseconds. In a phase change implementation in accordance with the principles of the present invention, the program delay may be reduced or eliminated, depending on whether program is used to write the memory cell to a high or low resistance state. In NAND, the handshaking signal, ready/busy, may be set to the “ready” state to signal to external circuitry that the memory is ready for more accesses. A verify command may be used to compare the data stored during the write operation to the data that was intended to be stored.

FLASH memory is not a direct over-write technology in writing to both cell states; memory must be erased to prepare it for a write operation to one of the states. An erase operation is initiated by sending a block erase command, followed by multiple cycles containing the address of the memory block to be erased. A ready/busy handshake signal is typically employed to indicate the availability of the memory for other operations to off-chip circuitry. Erasing a block of memory in preparation for a write operation may require several milliseconds. Although, in a phase-change technology implementation the bit state may be written directly to either state so that an erase operation is unnecessary, a multi-mode nonvolatile integrated circuit may maintain compatibility with a NAND FLASH devices (and existing firmware, software and controllers) by activating the ready signal into the Busy state in response to the receipt of a block erase command, for example, and then clearing the block selected (as is done for a NAND technology memory cell).

In an illustrative embodiment of a multi-mode nonvolatile integrated circuit memory in accordance with the principles of the present invention in which a NOR FLASH interface 202 is to be used, the memory with the embodiments herein may operate compatibly with other NOR or NAND FLASH memories using the same bus and command structures. Writing to a NOR FLASH memory involves sending a programming command to the NOR mode control register, followed by the data to be written and the address of the memory into which the data is to be written. A multi-mode nonvolatile integrated circuit memory in accordance with the principles of the present invention may include a NOR mode control register to accommodate such write commands by transferring data to write circuitry within the memory array 102 and address information to decoder circuitry 212. The NOR mode control register also responds to a verify command by compare the data written to memory to data that was intended to be written to memory.

In a NOR FLASH memory, memory cells must be erased before being written to. Whole blocks, not just individual memory cells or bytes of memory cells, must be erased upon command to a consistent bit state. As previously indicated, phase change cells need not be written to a “1” state, then erased, before being written to, as NOR FLASH cells typically are; however for compatibility such commands may be implemented. As a command option, the bits within a byte implemented in PCM may be written to requested bit state directly (either 1 or 0) within the byte. Thereby, the erase command may become unnecessary. However, for compatibility, the erase command may be retained and executed. Or the erase command may be redefined as a No-op (no operation is to be performed) within the mode control circuitry, through the use of embodiments described herein. Such mode control, for example, may be implemented at the factory by the chip manufacturer to fit the part ordered, by the OEM, or in the field.

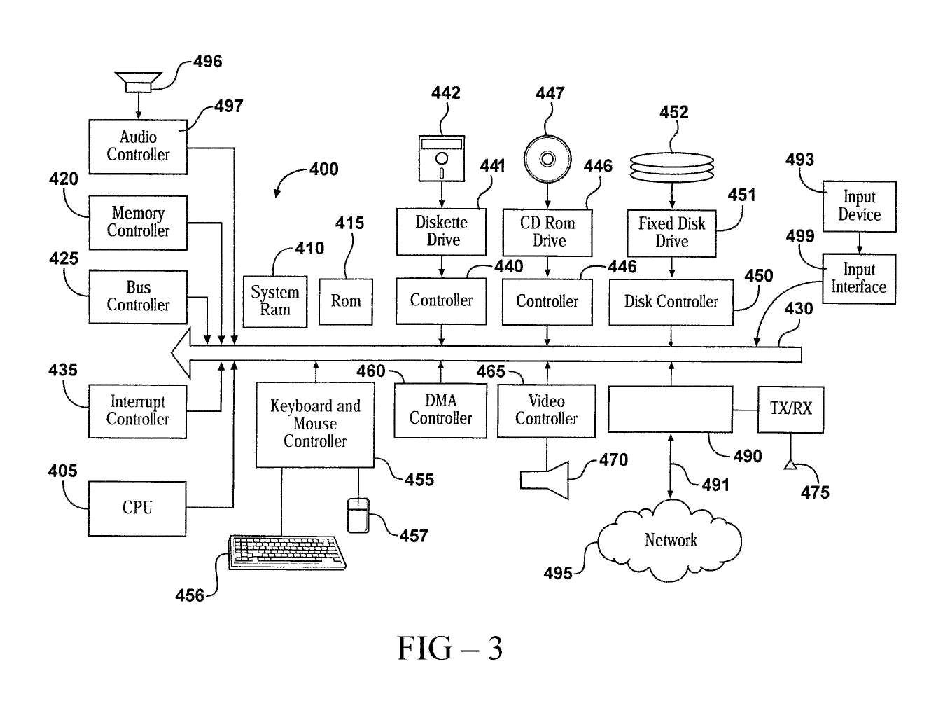

The electronic device(s) described in the discussion related to the previous figures may be employed to particular advantage in a wide variety of systems. The schematic diagram of FIG. 3 will be discussed to illustrate the devices' use in a few such systems. The schematic diagram of FIG. 3 includes many components and devices, some of which may be used for specific embodiments of a system in accordance with the principles of the present invention and others not used. In other embodiments, other similar systems, components and devices may be employed. In general, the system includes logic circuitry configured to operate along with phase change memory devices in accordance with the principles of the present invention with interfaces that may be defined on the chip using the present embodiments either at the factory, or by the OEM, or in the field—and such redefinition may be while the chip is operating for compatibility with one or more of the devices in FIG. 3. The logic circuitry may be discrete, programmable, application-specific, or in the form of a microprocessor, microcontroller, or digital signal processor, for example. The embodiments herein may be employed on integrated chips or connected to such circuitry. The exemplary system of FIG. 3 is for descriptive purposes only.

Although the description may refer to terms commonly used in describing particular computer, communications, tracking, and entertainment systems; the description and concepts equally apply to other systems, including systems having architectures dissimilar to that illustrated in FIG. 3. The electronic system 300, in various embodiments, may be implemented as, for example, a general purpose computer, a router, a large-scale data storage system, a portable computer, a personal digital assistant, a cellular telephone, an electronic entertainment device, such as a music or video playback device or electronic game, a microprocessor, a microcontroller, a digital signal processor, or a radio frequency identification device. Any or all of the components depicted in FIG. 3 may employ phase change memory devices or other memory technology with a redefinable interface in accordance with the principles of the present invention, for example.

In an illustrative embodiment, the system 400 may include a central processing unit (CPU) 405, which may include a microprocessor, a random access memory (RAM) 410 for temporary storage of information, and a read only memory (ROM) 415 for permanent storage of information. A memory controller 420 is provided for controlling RAM 410. In accordance with the principles of the present invention, all of, or any portion of, any of the memory elements (RAM, ROM, or disk, for example) may be implemented with nonvolatile memory in accordance with the principles of the present invention.

An electronic system 400 in accordance with the principles of the present invention may be a microprocessor that operates as a CPU 405, in combination with nonvolatile memory in accordance with the principles of the present invention that operates as RAM 410 and/or ROM 415, or as a portion thereof. In this illustrative example, the microprocessor/nonvolatile memory combination may be standalone, or may operate with other components, such as those of FIG. 3 yet-to-be described.

In implementations within the scope of the invention, a bus 430 interconnects the components of the system 400. A bus controller 425 is provided for controlling bus 430. An interrupt controller 435 may or may not be used for receiving and processing various interrupt signals from the system components. Such components as the bus 430, bus controller 425, and interrupt controller 435 may be employed in a large-scale implementation of a system in accordance with the principles of the present invention, such as that of a standalone computer, a router, a portable computer, or a data storage system, for example.

Mass storage may be provided by diskette 442, CD ROM 447, or hard drive 452. Data and software may be exchanged with the system 400 via removable media such as diskette 442 and CD ROM 447. Diskette 442 is insertable into diskette drive 441 which is, in turn, connected to bus 430 by a controller 440. Similarly, CD ROM 447 is insertable into CD ROM drive 446 which is, in turn, connected to bus 430 by controller 445. Hard disc 452 is part of a fixed disc drive 451 which is connected to bus 430 by controller 450. Although conventional terms for storage devices (e.g., diskette) are being employed in this description of a system in accordance with the principles of the present invention, any or all of the storage devices may be implemented using nonvolatile memory in accordance with the principles of the present invention. Removable storage may be provided by a nonvolatile storage component, such as a thumb drive, that employs nonvolatile memory in accordance with the principles of the present invention as the storage medium. Storage systems that employ nonvolatile memory in accordance with the principles of the present invention as “plug and play” substitutes for conventional removable memory, such as disks or CD ROMs or thumb drives, for example, may emulate existing controllers to provide a transparent interface for controllers such as controllers 440, 445, and 450, for example.

User input to the system 400 may be provided by any of a number of devices. For example, a keyboard 456 and mouse 457 are connected to bus 430 by controller 455. An audio transducer 496, which may act as both a microphone and/or a speaker, is connected to bus 430 by audio controller 497, as illustrated. Other input devices, such as a pen and/or tabloid may be connected to bus 430 and an appropriate controller and software, as required, for use as input devices. DMA controller 460 is provided for performing direct memory access to RAM 410, which, as previously described, may be implemented in whole or part using nonvolatile memory in accordance with the principles of the present invention. A visual display is generated by video controller 465 which controls display 470. The display 470 may be of any size or technology appropriate for a given application.

In a cellular telephone or portable entertainment system embodiment, for example, the display 470 may include one or more relatively small (e.g. on the order of a few inches per side) LCD displays. In a large-scale data storage system, the display may be implemented as large-scale multi-screen, liquid crystal displays (LCDs), or organic light emitting diodes (OLEDs), including quantum dot OLEDs, for example.

The system 400 may also include a communications adaptor 490 which allows the system to be interconnected to a local area network (LAN) or a wide area network (WAN), schematically illustrated by bus 491 and network 495. An input interface 499 (not shown) operates in conjunction with an input device 493 (not shown) to permit a user to send information, whether command and control, data, or other types of information, to the system 400. The input device and interface may be any of a number of common interface devices, such as a joystick, a touch-pad, a touch-screen, a speech-recognition device, or other known input device. In some embodiments of a system in accordance with the principles of the present invention, the adapter 490 may operate with transceiver 473 and antenna 475 to provide wireless communications, for example, in cellular telephone, RFID, and wifi computer implementations.

Operation of system 400 is generally controlled and coordinated by operating system software. The operating system controls allocation of system resources and performs tasks such as processing scheduling, memory management, networking, and I/O services, among other things. In particular, an operating system resident in system memory and running on CPU 405 coordinates the operation of the other elements of the system 400.

In illustrative handheld electronic device embodiments of a system 400 in accordance with the principles of the present invention, such as a cellular telephone, a personal digital assistance, a digital organizer, a laptop computer, a handheld information device, a handheld entertainment device such as a device that plays music and/or video, small-scale input devices, such as keypads, function keys and soft keys, such as are known in the art, may be substituted for the controller 455, keyboard 356 and mouse 457, for example. Embodiments with a transmitter, recording capability, etc., may also include a microphone input (not shown).

In an illustrative RFID transponder implementation of a system 400 in accordance with the principles of the present invention, the antenna 475 may be configured to intercept an interrogation signal from a base station at a frequency F. The intercepted interrogation signal would then be conducted to a tuning circuit (not shown) that accepts signal Fₗ and rejects all others. The signal then passes to the transceiver 473. where the modulations of the carrier Fₗ comprising the interrogation signal are detected, amplified and shaped in known fashion. The detected interrogation signal then passes to a decoder and logic circuit which may be implemented as discrete logic in a low power application, for example, or as a microprocessor/memory combination as previously described. The interrogation signal modulations may define a code to either read data out from or write data into nonvolatile memory in accordance with the principles of the present invention. In this illustrative embodiment, data read out from the memory is transferred to the transceiver 473 as an “answerback” signal on the antenna 475 at a second carrier frequency F₂. In passive RFID systems, power is derived from the interrogating signal and memory such as provided by nonvolatile memory in accordance with the principles of the present invention is particularly well suited to such use.

Mode control may be modified and the interface to the memory chip 100 may be redefined manually by the user or automatically by the system as needed. Such modification by the user may be, for example, by input from the keyboard of a PDA or computer. Similarly, the CPU or PDA may automatically change the interface as needed for operation with various attached devices such as a fixed disc drive which may be rotating media or solid state disc.

I claim:

1. An apparatus, comprising:
memory circuitry, including nonvolatile memory elements and memory input/output (I/O) circuitry, the I/O circuitry including I/O contacts; and
memory mode control circuitry configurable to modify the memory I/O circuitry to emulate the interface of one of a plurality of selectable memory modes.

2. The apparatus of claim 1, wherein the nonvolatile memory elements comprise phase change memory elements.

3. The apparatus of claim 2, wherein the memory mode control circuitry is configured to control the memory's I/O circuitry to emulate a NAND FLASH memory interface.

4. The apparatus of claim 2, wherein the memory mode control circuitry is configured to control the memory's I/O circuitry to emulate a NOR FLASH memory interface.

5. The apparatus of claim 2, wherein the memory mode control circuitry is configured to control the memory's I/O circuitry to emulate a dynamic random access memory (DRAM) interface.

6. The apparatus of claim 2, wherein the memory mode control circuitry is configured to control the memory's I/O circuitry to emulate a synchronous dynamic random access memory (SDRAM) interface.

7. The apparatus of claim 1, wherein the memory mode control circuitry is configurable to modify a signal path between an I/O contact and the memory circuitry.

8. The apparatus of claim 7, wherein the memory I/O circuitry includes a functional interface between the nonvolatile memory elements and wherein the mode control circuitry is configurable to modify the functional interface to correspond to the interface of the selected memory mode.

9. The apparatus of claim 8, wherein the nonvolatile memory elements comprise phase-change memory elements.

10. The apparatus of claim 9, wherein the selectable memory mode is selected from the group consisting of NOR FLASH, NAND FLASH, DRAM and SDRAM.

11. The apparatus of claim 1, wherein the memory mode control circuitry is configurable to modify a signal path between an I/O contact and the memory I/O circuitry.

12. An electronic system comprising:
an integrated circuit nonvolatile memory including phase change memory elements;
memory input/output (I/O) circuitry;
memory mode control circuitry configured to modify a signal path between an I/O contact and the memory I/O circuitry to emulate one of a plurality of selectable memory interfaces; and
controller circuitry configured to access the memory array.

13. The system of claim 12, further comprising a transceiver.

14. The system of claim 13, wherein the electronic system is configured as a radio frequency identification device (RFID).

15. The system of claim 13, wherein the electronic system is configured as a cellular telephone.

16. The system of claim 12, wherein the system is configured as a computer.
